(19) United States
(12) Patent Application Publication
(10) Pub. No.: US 2026/0004708 A1
(43) Pub. Date: Jan. 1, 2026

(54) DISPLAY PANEL AND DISPLAY APPARATUS

(71) Applicant: Tianma Advanced Display Technology Institute (Xiamen) Co.,Ltd., Xiamen (CN)

(72) Inventors: Zhenyu JIA, Xiamen (CN); Fanqing MENG, Xiamen (CN); Kerui XI, Xiamen (CN); Tianyi WU, Xiamen (CN); Yingteng ZHAI, Xiamen (CN); Liwei ZHANG, Xiamen (CN); Xueling LI, Xiamen (CN)

(21) Appl. No.: 18/914,839

(22) Filed: Oct. 14, 2024

(30) Foreign Application Priority Data
Jun. 28, 2024 (CN) 202410865508.1

(51) Int. Cl. G09G 3/32; H01L 25/16

(52) U.S. Cl. CPC G09G 3/32; G09G 2300/0426; G09G 2300/0842; G09G 2330/04; H01L 25/167

(57) ABSTRACT

The present disclosure provides a display panel and a display apparatus. The display panel includes a plurality of first signal lines; a plurality of power signal lines; and a plurality of electrostatic discharge circuits. The plurality of electrostatic discharge circuits includes a first electrostatic discharge circuit and a second electrostatic discharge circuit; the first electrostatic discharge circuit includes a first terminal and a second terminal, and the second electrostatic discharge circuit includes a first terminal and a second terminal; the first terminals of the first electrostatic discharge circuit and the second electrostatic discharge circuit are electrically connected to different first signal lines respectively; and the second terminals of the first electrostatic discharge circuit and the second electrostatic discharge circuit are electrically connected to different power signal lines respectively.

### CROSS-REFERENCE TO RELATED APPLICATION

The present disclosure claims the priority of Chinese Patent Application No. 202410865508.1, filed on Jun. 28, 2024, the content of which is incorporated herein by reference in its entirety.

### TECHNICAL FIELD

The present disclosure generally relates to the field of display technology and, more particularly, relates to a display panel and a display apparatus.

### BACKGROUND

With continuous update of display technology, display panels are gradually developing towards thinness, high screen-to-body ratio, and even borderless. In display panels driven by thin film transistors (TFT), electrostatic discharge (ESD) problems are caused by the inability to eliminate accumulated static electricity. Electrostatic discharge may cause damage to components in the display panels and affect product performance. Therefore, it needs to dispose electrostatic protection circuits on the display panels to discharge the electrostatic charges on the signal lines.

Existing display panels may use a set of power lines in the display panels, that is, the high-level power signal line VGH and the low-level power signal line VGL, to discharge the static electricity when electrostatic discharge circuits are designed. However, such design may cause leakage in the electrostatic discharge circuits, which may result in the electrostatic discharge circuits to interfere with panel normal operations.

### SUMMARY

One aspect of the present disclosure provides a display panel. The display panel includes a plurality of first signal lines; a plurality of power signal lines; and a plurality of electrostatic discharge circuits. The plurality of electrostatic discharge circuits includes a first electrostatic discharge circuit and a second electrostatic discharge circuit; the first electrostatic discharge circuit includes a first terminal and a second terminal, and the second electrostatic discharge circuit includes a first terminal and a second terminal; the first terminals of the first electrostatic discharge circuit and the second electrostatic discharge circuit are electrically connected to different first signal lines respectively; and the second terminals of the first electrostatic discharge circuit and the second electrostatic discharge circuit are electrically connected to different power signal lines respectively.

Another aspect of the present disclosure provides a display apparatus including a display panel. The display panel includes a plurality of first signal lines; a plurality of power signal lines; and a plurality of electrostatic discharge circuits. The plurality of electrostatic discharge circuits includes a first electrostatic discharge circuit and a second electrostatic discharge circuit; the first electrostatic discharge circuit includes a first terminal and a second terminal, and the second electrostatic discharge circuit includes a first terminal and a second terminal; the first terminals of the first electrostatic discharge circuit and the second electrostatic discharge circuit are electrically connected to different first signal lines respectively; and the second terminals of the first electrostatic discharge circuit and the second electrostatic discharge circuit are electrically connected to different power signal lines respectively.

Other aspects of the present disclosure may be understood by those skilled in the art in light of the description, the claims, and the drawings of the present disclosure.

### BRIEF DESCRIPTION OF THE DRAWINGS

In order to clearly explain embodiments of the present disclosure or the technical solutions in the existing technology, the drawings required for describing embodiments or the existing technology are briefly introduced hereinafter. Obviously, the drawings in the following description are merely embodiments of the present disclosure. Other drawings may also be obtained by those skilled in the art without any creative work according to provided drawings.

FIG. 1 illustrates a structural schematic of a display panel according to various embodiments of the present disclosure.

FIG. 2 illustrates a structural schematic of a pixel circuit in a display panel according to various embodiments of the present disclosure.

FIG. 3 illustrates a structural schematic of a driving circuit in a display panel according to various embodiments of the present disclosure.

FIG. 4 illustrates a structural schematic of a second display panel according to various embodiments of the present disclosure.

FIG. 5 illustrates a structural schematic of circuit wiring of a second display panel according to various embodiments of the present disclosure.

FIG. 6 illustrates a structural schematic of a third display panel according to various embodiments of the present disclosure.

FIG. 7 illustrates a structural schematic of a fourth display panel according to various embodiments of the present disclosure.

FIG. 8 illustrates a structural schematic of a fifth display panel according to various embodiments of the present disclosure.

FIG. 9 illustrates a structural schematic of a sixth display panel according to various embodiments of the present disclosure.

FIG. 10 illustrates a structural schematic of circuit wiring of a sixth display panel according to various embodiments of the present disclosure.

FIG. 11 illustrates a structural schematic of a seventh display panel according to various embodiments of the present disclosure.

FIG. 12 illustrates a structural schematic of connection relationship between shift register circuits, power signal lines, electrostatic discharge circuits and pixel circuits provided according to various embodiments of the present disclosure.

FIG. 13 illustrates a structural schematic of a display apparatus according to various embodiments of the present disclosure.

### DETAILED DESCRIPTION

The present disclosure is further described in detail below in conjunction with the accompanying drawings and embodiments. It is understood that the specific embodiments described herein are only configured to explain the present disclosure, not to limit the present disclosure. It should also be noted that, for the convenience of description, only parts of the present disclosure are shown in the drawings, not all structures.

The terms used in embodiments of the present disclosure may be only for the purpose of describing specific embodiments and may be not intended to limit the present disclosure. It should be noted that directional terms such as “upper”, “lower”, “left”, “right” and the like described in embodiments of the present disclosure may be described at the angles shown in the accompanying drawings and should not be understood as limiting embodiments of the present disclosure. In addition, in the context, it may also need to understand that when it is mentioned that an element is formed “on” or “under” another element, such element may not only be directly formed “on” or “under” another element, but also indirectly formed “on” or “under” another element through an intermediate element. The terms “first”, “second” and the like may be only used for descriptive purposes and may not indicate any order, quantity or importance, but may be only configured to distinguish different components. For those skilled in the art, specific meanings of the above terms in the present disclosure may be understood in specific circumstances.

The term “include”, and corresponding variations used in the present disclosure may be open inclusion, that is, “include but not limited to”. The term “based on” may indicate “at least partially based on”. The term “one embodiment” may indicate “at least one embodiment”. It should be noted that the concepts of “first” and “second” mentioned in the present disclosure may be only configured to distinguish corresponding contents and may be not configured to limit the order or interdependence. It should be noted that terms “one” and “a plurality of” mentioned in the present disclosure may be illustrative rather than restrictive; and those skilled in the art should understand that unless otherwise clearly stated in the context, those terms should be understood as “one or more”.

At present, with the complexity of the circuit structure of the display panel, different signal lines may be connected to different circuits, resulting in relatively large differences in the voltage range between signals transmitted on the signal lines. In order to ensure the stability of different signal lines with relatively large voltage range differences, the present disclosure provides corresponding electrostatic discharge circuit designs for signal lines with different voltage amplitude ranges.

For example, embodiments of the present disclosure provide a display panel. The display panel may include a plurality of first signal lines, a plurality of power signal lines, and a plurality of electrostatic discharge circuits; the plurality of electrostatic discharge circuits may include a first electrostatic discharge circuit and a second electrostatic discharge circuit; the first electrostatic discharge circuit and the second electrostatic discharge circuit may both include a first terminal and a second terminal; the first terminals of the first electrostatic discharge circuit and the second electrostatic discharge circuit may be electrically connected to different first signal lines respectively; the second terminals of the first electrostatic discharge circuit and the second electrostatic discharge circuit may be electrically connected to different power signal lines respectively.

In above-mentioned technical solution, the first terminals of the first electrostatic discharge circuit and the second electrostatic discharge circuit may be electrically connected to different first signal lines, and the second terminals of the first electrostatic discharge circuit and the second electrostatic discharge circuit may be electrically connected to different first signal lines may be electrically connected to different power signal lines. The essence may be for the electrostatic discharge circuits of the first signal lines connected to different voltage domains to perform electrostatic discharge through the power signal lines adapted to the voltage domain. Therefore, for the electrostatic discharge circuit, the first signal line receiving the electrostatic source and the power signal line for electrostatic discharge may have adaptive voltage domains. In the absence of static electricity, the electrostatic discharge circuit may be normally in a turn-off state. In the case of static electricity generated by the display panel, the electrostatic discharge circuit may be turned on normally to discharge the static electricity of the first signal line through the power signal line to protect the safety of the display panel. Embodiments of the present disclosure solve the problem that existing electrostatic discharge of different signal lines through same power signal line may easily cause leakage of the electrostatic discharge circuits and affect normal driving of the display panel, which may realize the accurate turn-on and turn-off of the electrostatic discharge circuits, ensure the effective electrostatic discharge when static electricity is generated and avoid the design problems of the electrostatic discharge circuits from affecting normal driving of the display panel, thereby being beneficial for improving the quality and performance of the display panel.

The above may be core concept of the present disclosure. The technical solutions in embodiments of the present disclosure are clearly and completely described in conjunction with accompanying drawings in embodiments of the present disclosure hereinafter. Based on embodiments of the present disclosure, all other embodiments obtained by those skilled in the art without creative work may be within the scope of protection of the present disclosure.

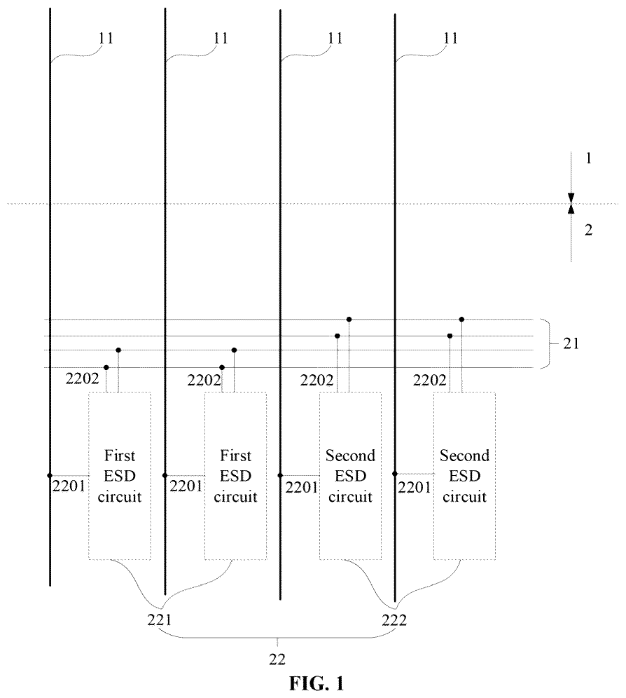

FIG. 1 illustrates a structural schematic of a display panel according to various embodiments of the present disclosure. Referring to FIG. 1, in embodiments of the present disclosure, the display panel may include a pixel driving region 1 and an electrostatic discharge (ESD) region 2; the pixel driving region 1 may include a plurality of first signal lines 11 which may extend through the electrostatic discharge region 2; the electrostatic discharge region 2 may include a plurality of power signal lines 21 and a plurality of electrostatic discharge (ESD) circuits 22; the plurality of electrostatic discharge circuits 22 may include a first electrostatic discharge (ESD) circuit 221 and a second electrostatic discharge (ESD) circuit 222; the first electrostatic discharge circuit 221 and the second electrostatic discharge circuit 222 may both include a first terminal 2201 and a second terminal 2202; the first terminals 2201 of the first electrostatic discharge circuit 221 and the second electrostatic discharge circuit 222 may be electrically connected to different first signal lines 11 respectively; and the second terminals 2202 of the first electrostatic discharge circuit 221 and the second electrostatic discharge circuit 222 may be electrically connected to different power signal lines 21 respectively.

The pixel driving region 1 may be understood as the region where the pixel circuit for driving display is in the display panel. The pixel driving region 1 may include the plurality of first signal lines 11. All first signal lines 11 may extend through the electrostatic discharge region 2, and all first signal lines 11 may be independent of each other. When static electricity is generated on the display panel due to friction and the like, in order to prevent the first signal lines 11 from being affected by static electricity to damage the pixel circuit and affect the driving display function, the static electricity on the first signal lines 11 may be conducted out of the display panel. For example, the electrostatic discharge circuit 22 may be disposed in the electrostatic discharge region 2, and two terminals of the electrostatic discharge circuit 22 may be respectively connected to the first signal line 11 and the power signal line 21, which is responsible for releasing the static electricity on the first signal line 11. When static electricity is generated on the first signal line 11, the electrostatic discharge circuit 22 may be automatically turned on by the electrostatic signal control, and the static electricity may be conducted (discharged) to the outside through the power signal line 21 via the turned-on electrostatic discharge circuit. The material of the power signal line 21 may be a conductive metal material, for example, including but not limited to any one of copper, molybdenum, titanium and aluminum.

It should be noted that the pixel driving region 1 and the electrostatic discharge region 2 may be divided according to the types of circuit structures configured therein. The display panel in embodiments of the present disclosure may be a display without frame. That is, the light-emitting elements driven by the pixel circuits may be arranged in various regions of entire display panel, and all regions of the display panel may be display regions. The light-emitting elements and the circuit structures may be in different film layers of the display panel. It may be seen that, as shown in FIG. 1, the pixel driving region 1 and the electrostatic discharge region 2 may be substantially included in the display region. Obviously, the display panel in other embodiments of the present disclosure may also be divided into a display region and a non-display region according to the position of the light-emitting elements, and the electrostatic discharge region 2 may be configured in the non-display region.

In one embodiment, the electrostatic discharge region 2 may include the plurality of power signal lines 21 and the plurality of electrostatic discharge circuits 22. The plurality of power signal lines 21 may be configured to discharge the electrostatic voltage signals generated by the first signal lines 11 through the electrostatic discharge circuits 22 and the power signal lines 21. The plurality of electrostatic discharge circuits 22 may include the first electrostatic discharge circuit 221 and the second electrostatic discharge circuit 222; and the first electrostatic discharge circuit 221 and the second electrostatic discharge circuit 222 may both include the first terminal 2201 and the second terminal 2202. The first terminals 2201 of the first electrostatic discharge circuit 221 and the second electrostatic discharge circuit 222 may be electrically connected to different first signal lines 11, respectively, such that the electrostatic voltage signal of each first signal line 11 may be transmitted to the first electrostatic discharge circuit 221 and the second electrostatic discharge circuit 222. The second terminals 2202 of the first electrostatic discharge circuit 221 and the second electrostatic discharge circuit 222 may be electrically connected to different power signal lines 21, respectively, such that, after passing through the second terminals 2202 of the first electrostatic discharge circuit 221 and the second electrostatic discharge circuit 222, the electrostatic voltage signals may be transmitted to different power signal lines 21, and the electrostatic voltage signals may be electrostatically discharged through different power signal lines 21.

Optionally, the power signal line may be a signal line with a fixed potential or a signal line with a non-fixed potential.

Optionally, the display panel in the present disclosure may include at least two sub-circuits. The two subcircuits may be from different modules of same circuit (such as the width modulation circuit (PWM) and pulse width modulation circuit (PAM) modules described below); or may be from different circuits, for example, the two subcircuits may be a voltage sensitive relay (VSR) circuit and a pixel circuit, respectively. The two sub-circuits may be each electrically connected to one power signal line 21, and the difference in the power signal lines 21 of the two sub-circuits may be that the functions of the signal lines may be different, or the sizes of the signals transmitted by the signal lines may be different, or the amplitudes of the signals may be different. Two different power signal lines 21 may be respectively connected to the first electrostatic discharge circuit 221 and the second electrostatic discharge circuit 222.

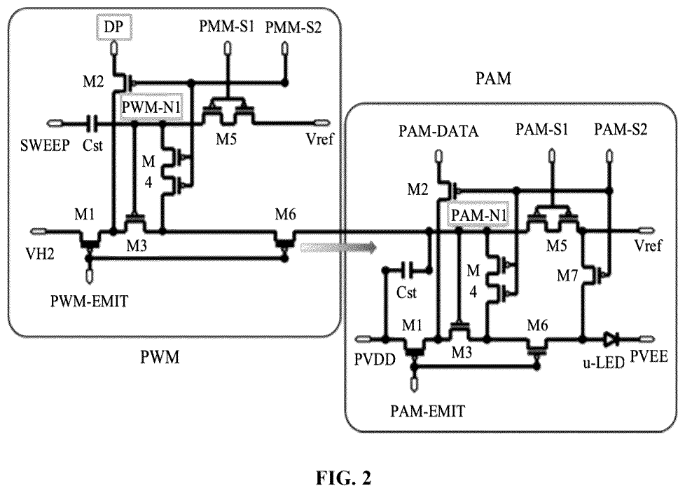

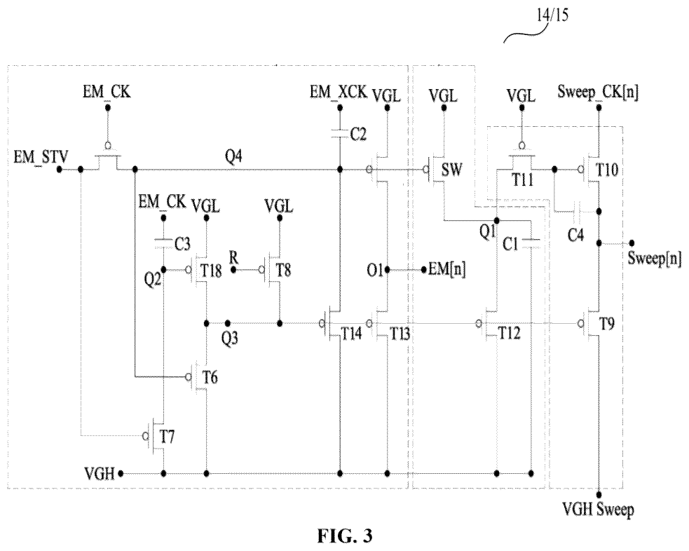

FIG. 2 illustrates a structural schematic of a pixel circuit in a display panel according to various embodiments of the present disclosure; and FIG. 3 illustrates a structural schematic of a driving circuit in a display panel according to various embodiments of the present disclosure. Referring to FIGS. 2-3, the principle of the electrostatic discharge circuit design in embodiments of the present disclosure is described in detail hereinafter.

Firstly, referring to FIGS. 2-3, exemplarily, the pixel circuit in the display panel of the present disclosure may include a pulse amplitude modulation (PAM) circuit and a pulse width modulation (PWM) circuit; and the pulse amplitude modulation circuit (PAM) and the pulse width modulation circuit (PWM) may require different scanning signals for driving control during normal operation. Exemplarily, the driving circuit in FIG. 3 may be configured to provide a certain signal to the pulse width modulation circuit (PWM) or the pulse amplitude modulation circuit (PAM). For example, exemplary driving circuit in FIG. 3 may provide a Sweep[n] signal to the pulse width modulation circuit (PWM). In addition, the driving circuits that provide scanning signals to the pulse amplitude modulation circuit (PAM) and the pulse width modulation circuit (PWM) may respectively have different voltage domains. For example, in the driving circuit that provides the scanning signals to the pulse width modulation circuit (PWM), the signal voltages of the power signals VGH and VGL may be +8V and −7V respectively; and in the driving circuit that provides the scanning signals to the pulse width modulation circuit (PWM), the signal voltages of the power signals VGH and VGL may be +3V and −12V respectively.

It should be noted that when the driving signals in the pixel circuit perform electrostatic discharge, if the electrostatic discharge circuit uses a same group of power signal lines for electrostatic discharge, exemplarily, when the driving signals of the pixel circuit in FIG. 2 (that is, the pulse amplitude modulation circuit (PAM) and the pulse width modulation circuit (PWM)) perform electrostatic discharge, the power signal lines VGH and VGL of +3\−12V may be configured for electrostatic discharge. However, for the driving signal in the pulse width modulation circuit (PWM), the voltage domain may be +8˜−7V. After these driving signal lines are connected to the electrostatic discharge circuits, the electrostatic discharge circuits may be mistakenly turned on because the voltage domain (+8˜−7V) is higher than the power signal line (+3˜−12V) connected to the electrostatic discharge circuit, which may result in leakage problems and affect normal driving of the pixel circuit and the performance of the display panel.

However, as shown in FIG. 1, in embodiments of the present disclosure, when the signal lines in the pixel circuit in FIG. 2 (that is, the pulse amplitude modulation circuit (PAM) and the pulse width modulation circuit (PWM)) are subjected to electrostatic discharge, according to different voltage domains of the first signal lines 11, the first terminals 2201 of the first electrostatic discharge circuit 221 and the second electrostatic discharge circuit 222 may be electrically connected to the first signal lines 11 of different voltage domains, respectively. For example, the first terminal 2201 of the first electrostatic discharge circuit 221 may be connected to the signal line of the pulse width modulation circuit (PWM) (voltage domain is +8˜−7V), and the first terminal 2201 of the second electrostatic discharge circuit 222 may be connected to the signal line of the pulse amplitude modulation circuit (PAM) (voltage domain is +3˜−12V). Meanwhile, the second terminals 2202 may be electrically connected to the power signal lines 21 of different voltage domains. For example, the second terminal 2202 of the first electrostatic discharge circuit 221 may be electrically connected to the power signal line 21 with a voltage domain of +8˜−7V, and the second terminal 2202 of the second electrostatic discharge circuit 222 may be electrically connected to the power signal line 21 with a voltage domain of +3˜−12V. In such way, it may be ensured that two terminals of the first electrostatic discharge circuit 221 and the second electrostatic discharge circuit 222 may be respectively connected to the first signal line 11 and the power signal line 21 with matching voltage domains. Therefore, it may avoid that the electrostatic discharge circuit is mistakenly turned on due to the voltage domain (+8˜−7V) of the first signal line 11 being higher than the voltage domain (+3˜−12V) of the power signal line 21 connected to the electrostatic discharge circuit, which may result in leakage problem and affect normal driving of the pixel circuit and the performance of the display panel. Accurate on-off of the electrostatic discharge circuit may be achieved, which may ensure that generated static electricity may be effectively discharged, prevent the design problem of the electrostatic discharge circuit from affecting normal driving of the display panel, thereby improving the quality and performance of the display panel.

It should be noted that the second terminals 2202 of the first electrostatic discharge circuit 221 and the second electrostatic discharge circuit 222 may be electrically connected to different power signal lines 21. In one embodiment, the numbers of the second terminals 2202 of the first electrostatic discharge circuit 221 and the second electrostatic discharge circuit 222, that is, the quantity of electrostatic output terminals, may be at least two. Two electrostatic output terminals may be respectively connected to different power signal lines 21 of same group. That is, the high-level voltage VGH and the low-level voltage VGL may form a group, and two electrostatic output terminals may be respectively connected to the high-level voltage VGH and the low-level voltage VGL of same group. When the electrostatic voltage is high-voltage static electricity, the high-voltage static electricity may be transmitted to the electrostatic discharge circuit, such that the electrostatic discharge circuit may work normally; and the high-voltage static electricity may be finally outputted through the second terminal 2202 of the electrostatic discharge circuit and transmitted to corresponding power signal line 21 of the high-level voltage VGH, such that the high-voltage static electricity inside the panel may be discharged by the high-level voltage VGH. When the electrostatic voltage is low-voltage static electricity, the low-voltage static electricity may be transmitted to the electrostatic discharge circuit, such that the electrostatic discharge circuit may work normally; and the low-voltage static electricity may be finally outputted through the second terminal 2202 of the electrostatic discharge circuit and transmitted to the power signal line 21 of corresponding low-level voltage VGL, such that the low-voltage static electricity inside the panel may be discharged by the low-level voltage VGL.

For the technical solutions of embodiments of the present disclosure, the first terminals of the first electrostatic discharge circuit and the second electrostatic discharge circuit may be electrically connected to different first signal lines respectively, and the second terminals of the first electrostatic discharge circuit and the second electrostatic discharge circuit may be electrically connected to different power signal lines respectively. The essence may be for the electrostatic discharge circuits of the first signal lines connected to different voltage domains to perform electrostatic discharge through the power signal lines adapted to the voltage domain. Therefore, for the electrostatic discharge circuit, the first signal line receiving the electrostatic source and the power signal line for electrostatic discharge may have adaptive voltage domains. In the absence of static electricity, the electrostatic discharge circuit may be normally in a turn-off state. In the case of static electricity generated by the display panel, the electrostatic discharge circuit may be turned on normally to discharge the static electricity of the first signal line through the power signal line to protect the safety of the display panel. Embodiments of the present disclosure solve the problem that existing electrostatic discharge of different signal lines through same power signal line may easily cause leakage of the electrostatic discharge circuits and affect normal driving of the display panel, which may realize the accurate turn-on and turn-off of the electrostatic discharge circuits, ensure the effective electrostatic discharge when static electricity is generated and avoid the design problems of the electrostatic discharge circuits from affecting normal driving of the display panel, thereby being beneficial for improving the quality and performance of the display panel.

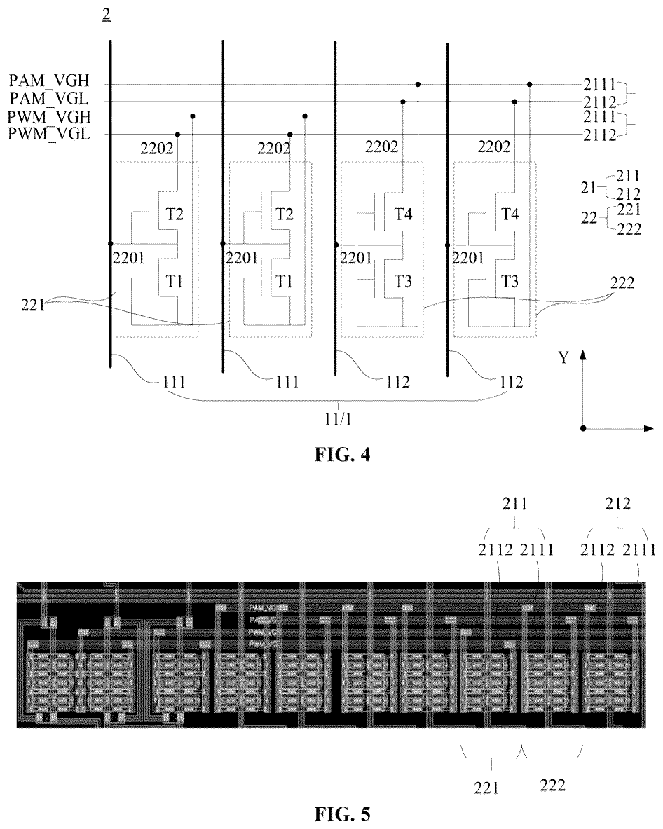

Optionally, FIG. 4 illustrates a structural schematic of a second display panel according to various embodiments of the present disclosure; and FIG. 5 illustrates a structural schematic of circuit wiring of a second display panel according to various embodiments of the present disclosure. Referring to FIGS. 4-5, the signal range of the power signal line 21 electrically connected to the first electrostatic discharge circuit 221 may be different from the signal range of the power signal line 21 electrically connected to the second electrostatic discharge circuit 222.

For example, the plurality of power signal lines 21 may include a first group of power signal lines 211 and a second group of power signal lines 212; the first group of power signal lines 211 may include a first power signal line 2111 and a second power signal line 2112; the second group of power signal lines 212 may include a first power signal line 2111 and a second power signal line 2112; in the first group of power signal lines 211, the power signal voltage of the first power signal line 2111 may be V11, and the power signal voltage of the second power signal line 2112 may be V12; in the second group of power signal lines 212, the power signal voltage of the first power signal line 2111 may be V21, and the power signal voltage of the second power signal line 21112 may be V22, where V11>V12, V21>V22, V11≠V21, and V12≠V22; two second terminals 2202 of the first electrostatic discharge circuit 221 may be electrically connected to the first power signal line 2111 and the second power signal line 2112 in the first group of power signal lines 211 respectively; and two second terminals 2202 of the second electrostatic discharge circuit 222 may be electrically connected to the first power signal line 2111 and the second power signal line 2112 in the second group of power signal lines 212 respectively.

For example, the first group of power signal lines 211 may be the power signal lines of the pulse width modulation (PWM) circuits, and the second group of power signal lines 212 may be the power signal lines of the pulse amplitude modulation (PAM) circuits. The first group of power signal lines 211 and the second group of power signal lines 212 may each include the first power signal line 2111 and the second power signal line 2112, where the first power signal line 2111 may be the high-level signal line VGH, and the second power signal line 2112 may be the low-level signal line VGL. In the first group of power signal lines 211, the power signal voltage of the first power signal line 2111 may be V11, and the power signal voltage of the second power signal line 2112 may be V12. That is, in the power signal lines of the pulse width modulation circuits, the power signal voltage of the high level signal line VGH may be V11, and the power signal voltage of the low level signal line VGL may be V12, where V11 may be +8V, and V12 may be −7V. In the second group of power signal lines 212, the power signal voltage of the first power signal line 2111 may be V21, and the power signal voltage of the second power signal line 2112 may be V22. That is, in the power signal lines of the pulse amplitude modulation circuits, the power signal voltage of the high-level signal line VGH may be V21, and the power signal voltage of the low-level signal line VGL may be V22, where V12 may be +3V and V22 may be −12V. In addition, the first power signal line 2111 is the high-level signal line VGH and the second power signal line 2112 is the low-level signal line VGL, therefore the power signal voltage V11 (V21) of the first power signal line 2111 may be greater than the power signal voltage V12 (V22) of the second power signal line 2112; that is, V11>V12, and V21>V22. In addition, V11V21, and V12V22. That is, the power signal voltage V11 of the first power signal line 2111 in the first group of power signal lines 211 may be different from the power signal voltage V21 of the first power signal line 2111 in the second group of power signal lines 212; and the power signal voltage V12 of the second power signal line 2112 in the first group of power signal lines 211 may be different from the power signal voltage V22 of the second power signal line 2112 in the second group of power signal lines 212, which may be determined according to actual conditions and may not be limited herein.

In addition, through one embodiment, the signal ranges of two different power signal lines 21 may be provided. Therefore, the electrostatic discharge circuits may each have a more accurate electrostatic discharge control capability, and optional range of the electrostatic discharge of the display panel as a whole may also become wide, thereby providing more optional space for the signal selection of the circuits while further ensuring the electrostatic discharge safety performance.

Obviously, in some optional embodiments of the present disclosure, the signal range of the power signal line 21 electrically connected to the first electrostatic discharge circuit 221 and the signal range of the power signal line 21 electrically connected to the second electrostatic discharge circuit 222 may be overlapped with each other.

In some optional embodiments of the present disclosure, the signal range of the power signal line 21 electrically connected to the first electrostatic discharge circuit 221 and the signal range of the power signal line 21 electrically connected to the second electrostatic discharge circuit 222 may not be overlapped with each other.

In some optional embodiments of the present disclosure, the signal range of the power signal line 21 electrically connected to the first electrostatic discharge circuit 221 may include the signal range of the power signal line 21 electrically connected to the second electrostatic discharge circuit 222, or vice versa.

In addition, as mentioned above, two second terminals 2202 of the first electrostatic discharge circuit 221 may be respectively and electrically connected to the first power signal line 2111 and the second power signal line 2112 in the first group of power signal lines 211; and two second terminals 2202 of the second electrostatic discharge circuit 222 may be respectively and electrically connected to the first power signal line 2111 and the second power signal line 2112 in the second group of power signal lines 212. The first power signal line 2111 may be the high-level signal line VGH, and the second power signal line 2112 may be the low-level signal line VGL. The objective of above configuration may be that for any one of the first electrostatic discharge circuit 221 and the second electrostatic discharge circuit 222, when there is high-voltage static electricity on the first signal line 11 connected thereto, the electrostatic discharge circuit 22 may be turned on by the high-voltage static electricity, and the electrostatic discharge circuit 22 may transmit the high-voltage static electricity to the first power signal line 2111 of corresponding high-level voltage VGH through one of the second terminals 2202, thereby realizing the discharge of the high-voltage static electricity. Similarly, when there is low-voltage static electricity on the first signal line 11 connected thereto, the electrostatic discharge circuit 22 may be turned on by the low-voltage static electricity, and the electrostatic discharge circuit 22 may transmit the low-voltage static electricity to the second power signal line 2111 of corresponding low-level voltage VGL connected through another second terminal 2202, thereby realizing the discharge of low-voltage static electricity. In such way, when there are different types of (high voltage or low voltage) static electricity in the panel, the electrostatic discharge circuit 22 in the present disclosure may achieve effective static electricity discharge effect on the first signal line 11 connected thereto, which may avoid static electricity problems from damaging the panel and ensure normal display of the display panel.

$$Optionally , ( V 11 - V 21 ) \times ( V 12 - V 22 ) > 0.$$

$$Optionally , V 11 - V 21 = V 12 - V 22.$$

$$Optionally , V 11 - V 12 = V 21 - V 22.$$

For example, it may configure that (V11−V21)×(V12−V22)>0, and V11−V21=V12−V22. That is, the difference between the power signal voltage V11 of the first power signal line 2111 in the first group of power signal lines 211 and the power signal voltage V21 of the first power signal line 2111 in the second group of power signal lines 212 may be equal to the difference between the power signal voltage V12 of the second power signal line 2112 in the first group of power signal lines 211 and the power signal voltage V22 of the second power signal line 2112 in the second group of power signal lines 212; and the product of above two differences may be positive. That also is, when the difference between the power signal voltage V11 of the first power signal line 2111 in the first group of power signal lines 211 and the power signal voltage V21 of the first power signal line 2111 in the second group of power signal lines 212 is positive, corresponding difference between the power signal voltage V12 of the second power signal line 2112 in the first group of power signal lines 211 and the power signal voltage V22 of the second power signal line 2112 in the second group of power signal lines 212 may be also positive; and when the difference between the power signal voltage V11 of the first power signal line 2111 in the first group of power signal lines 211 and the power signal voltage V21 of the first power signal line 2111 in the second group of power signal lines 212 is negative, the difference between the power signal voltage V12 of the second power signal line 2112 in the corresponding first group of power signal lines 211 and the power signal voltage V22 of the second power signal line 2112 in the second group of power signal lines 212 may be also negative. In one embodiment, V11 is +8V, V12 is −7V, V21 is +3V, V22 is −12V, the difference between V11 and V21 is +5V, the difference between V12 and V22 is +5V, the difference between V11 and V21 may be equal to the difference between V12 and V22, and the product of above differences is +25V which is a positive number.

In addition, in one embodiment, it configures that V11−V12=V21−V22. That is, the difference between the power signal voltage V11 of the first power signal line 2111 in the first group of power signal lines 211 and the power signal voltage V12 of the second power signal line 2112 in the first group of power signal lines 211 may be equal to the difference between the power signal voltage V21 of the first power signal line 2111 in the second group of power signal lines 212 and the power signal voltage V22 of the second power signal line 2112 in the second group of power signal lines 212. In one embodiment, V11 is +8V, V12 is +3V, V21 is −7V, V22 is −12V, the difference between V11 and V12 is 5V, the difference between V21 and V22 is 5V, and above two differences are equal to each other.

Optionally, referring to FIG. 4, the first electrostatic discharge circuit 221 may include a first transistor T1 and a second transistor T2; the control terminal and the first terminal of the first transistor T1 may be both electrically connected to the first power signal line 2111 in the first group of power signal lines 211, and the second terminal of the first transistor T1 may be respectively and electrically connected to the control terminal and the first terminal of the second transistor T2 and electrically connected to the first signal line 11 as the first terminal 2201; the second terminal of the second transistor T2 may be electrically connected to the second power signal line 2112 in the first group of power signal lines 211; the second electrostatic discharge circuit 222 may include a third transistor T3 and a fourth transistor T4; the control terminal and the first terminal of the third transistor T3 may be both electrically connected to the first power signal line 2111 in the second group of power signal lines 212, and the second terminal of the third transistor T3 may be respectively and electrically connected to the control terminal and the first terminal of the fourth transistor T4 and electrically connected to the first signal line 11 as the first terminal 2201; and the second terminal of the fourth transistor T4 may be electrically connected to the second power signal line 2112 in the second group of power signal lines 212.

The first transistor T1, the second transistor T2, the third transistor T3 and the fourth transistor T4 may be N-type channel transistors as shown in FIG. 4 or may be P-type channel transistors, which may be not limited herein. The first transistor T1, the second transistor T2, the third transistor T3 and the fourth transistor T4 as N-type channel transistors may be taken as an example. For example, for the first electrostatic discharge circuit 221, when the first signal line 11 generates high-voltage static electricity, the high-voltage electrostatic voltage signal of the first signal line 11 may be inputted to the first terminal 2201 of the first electrostatic discharge circuit 221. At this point, the first transistor T1 may be turned on to be in conduction, and the high-voltage electrostatic signal may be discharged to the first power signal line 2111 of the high-level voltage VGH in the first group of power signal lines 211 through the first transistor T1. When the first signal line 11 generates low-voltage static electricity, the low-voltage electrostatic voltage signal of the first signal line 11 may be inputted to the first terminal 2201 of the first electrostatic discharge circuit 221. At this point, the second transistor T2 may be turned on to be in conduction, and the low-voltage electrostatic signal may be discharged to the second power signal line 2112 of the low-level voltage VGL in the first group of power signal lines 211 through the second transistor T2, thereby realizing electrostatic discharge. For the second electrostatic discharge circuit 222, similarly, when the first signal line 11 generates high- voltage static electricity, the high-voltage electrostatic voltage signal of the first signal line 11 may be inputted to the first terminal 2201 of the second electrostatic discharge circuit 222. At this point, the third transistor T3 may be turned on to be conduction, and the high-voltage electrostatic signal may be discharged to the first power signal line 2111 of the high-level voltage VGH in the second power signal line 212 through the third transistor T3. When the first signal line 11 generates low-voltage static electricity, the low-voltage electrostatic voltage signal of the first signal line 11 may be inputted to the first terminal 2201 of the second electrostatic discharge circuit 222. At this point, the fourth transistor T4 may be turned on in conduction, and the low-voltage electrostatic signal may be discharged to the second power signal line 2112 of the low-level voltage VGL in the second group of power signal lines 212 through the fourth transistor T4, thereby realizing electrostatic discharge. As disclosed above, the first electrostatic discharge circuit 221 and the second electrostatic discharge circuit 222 may effectively discharge the high-voltage and low-voltage static electricity generated in the display panel, thereby preventing static electricity from damaging the internal structure of the panel and ensuring the quality and performance of the display panel.

Optionally, referring to FIGS. 4-5, the plurality of electrostatic discharge circuits 22 may be arranged along the first direction X; and the first power signal line 2111 and the second power signal line 2112 may extend along the first direction X. In such way, when two second terminals 2202 of the first electrostatic discharge circuit 221 are respectively and electrically connected to the first power signal line 2111 and the second power signal line 2112 of the first group of power signal lines 211, and when two second terminals 2202 of the second electrostatic discharge circuit 222 are respectively and electrically connected to the first power signal line 2111 and the second power signal line 2112 of the second group of power signal lines 212, the first electrostatic discharge circuit 221 and the second electrostatic discharge circuit 222 may be arranged reasonably and compactly, and the region of the display panel may be effectively utilized to improve the utilization rate of the display panel.

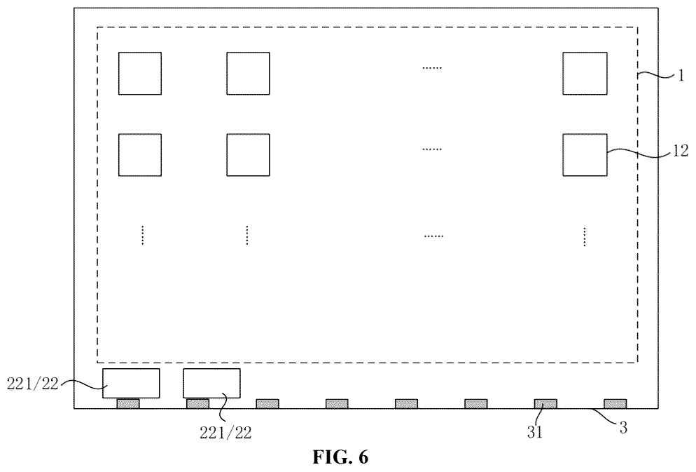

Optionally, FIG. 6 illustrates a structural schematic of a third display panel according to various embodiments of the present disclosure. Referring to FIG. 6, the pixel driving region 1 may also include a plurality of pixel circuits 12 and a plurality of light-emitting elements (not shown in drawings), the pixel circuit 12 may be configured to provide a driving current to the light-emitting element; the electrostatic discharge circuit 22 may be between the plurality of pixel circuits 12 and the first edge 3 of the display panel. For example, the first edge 3 may be the edge of the display panel closest to the electrostatic discharge circuit 22.

For example, the pixel circuit 12 may be a pixel circuit. The pixel circuit 12 may be configured to provide a driving current to the light-emitting element, such that the light-emitting element may emit light of different brightnesses according to the amplitude of received driving current. The light-emitting element may be a component for emitting light. In one embodiment, the light-emitting element may be a micro light-emitting diode (Micro-LED). In addition, the first edge 3 may be the edge of the display panel closest to the electrostatic discharge circuit 22. Referring to FIG. 6, the first edge 3 may be the lower edge of the display panel, and the electrostatic discharge circuit 22 may be between the plurality of pixel circuits 12 and the first edge 3 of the display panel, such that the electrostatic discharge circuit 22 may realize normal discharge of the electrostatic voltage signal.

Referring to FIG. 6, in an optional embodiment, the first edge 3 may be disposed with side wires 31. In one embodiment, the display panel may be essentially a frameless display panel. A driving structure, such as a driving chip, a flexible circuit board connected to a driving motherboard or the like, may be disposed on the back of the display panel. The driving structure may be connected to the front of the display panel through the side wires 31, and responsible for providing power signals, driving signals, timing signals and the like to the display panel to control the display panel to realize the display function.

Optionally, referring to FIGS. 4 and 6, along the second direction Y, the first power signal line 2111 may be on the side of the electrostatic discharge circuit 22 adjacent to or away from the first edge 3 of the display panel, and the second power signal line 2112 may be on the side of the electrostatic discharge circuit 22 adjacent to or away from the first edge 3 of the display panel; and the first edge 3 may be the edge of the display panel that is closest to the electrostatic discharge circuit 22, where the second direction Y may be perpendicular to the first direction X.

For example, the first direction X may be perpendicular to the second direction Y. In one embodiment, the first direction X may be a horizontal direction, and the second direction Y may be a vertical direction. Along the second direction Y, the first power signal line 2111 may be on the side of the electrostatic discharge circuit 22 adjacent to or away from the first edge 3 of the display panel, and the second power signal line 2112 may be on the side of the electrostatic discharge circuit 22 adjacent to or away from the first edge 3 of the display panel. That is, the first power signal line 2111 and the second power signal line 2112 may be on same side or different sides. When the first power signal line 2111 and the second power signal line 2112 are on same side, the first power signal line 2111 and the second power signal line 2112 may be both on the side of the electrostatic discharge circuit 22 adjacent to the first edge 3 of the display panel, or on the side of the electrostatic discharge circuit 22 away from the first edge 3 of the display panel. When the first power signal line 2111 and the second power signal line 2112 are on different sides, the first power signal line 2111 may be on the side of the electrostatic discharge circuit 22 adjacent to the first edge 3 of the display panel, and the second power signal line 2112 may be on the side of the electrostatic discharge circuit 22 away from the first edge 3 of the display panel; or the first power signal line 2111 may be on the side of the electrostatic discharge circuit 22 away from the first edge 3 of the display panel, and the second power signal line 2112 may be on the side of the electrostatic discharge circuit 22 adjacent to the first edge 3 of the display panel, which may be determined according to actual situations and may not be limited herein. When the first power signal line 2111 and/or the second power signal line 2112 are on the side of the electrostatic discharge circuit 22 adjacent to the first edge 3 of the display panel, it indicates that the first power signal line 2111 and/or the second power signal line 2112 may be between the electrostatic discharge circuit 22 and the first edge 3. When the first power signal line 2111 and/or the second power signal line 2112 are on the side of the electrostatic discharge circuit 22 away from the first edge 3 of the display panel, it indicates that the first power signal line 2111 and/or the second power signal line 2112 may be above the electrostatic discharge circuit 22.

It may be understood that FIG. 4 only shows a schematic diagram in which the first power signal line 2111 and the second power signal line 2112 are on same side and both on the side of the electrostatic discharge circuit 22 away from the first edge 3 of the display panel; and other situations may be adjusted according to FIG. 4.

Optionally, referring to FIGS. 4 and 6, along the second direction Y, the first power signal line 2111 and the second power signal line 2112 may be both on the side of the electrostatic discharge circuit 22 away from the first edge 3 of the display panel.

For example, along the second direction Y, the first power signal line 2111 and the second power signal line 2112 may be both on the side of the electrostatic discharge circuit 22 away from the first edge 3 of the display panel. That is, the first power signal line 2111 and the second power signal line 2112 may be on same side and are both above the electrostatic discharge circuit 22 and the first edge 3.

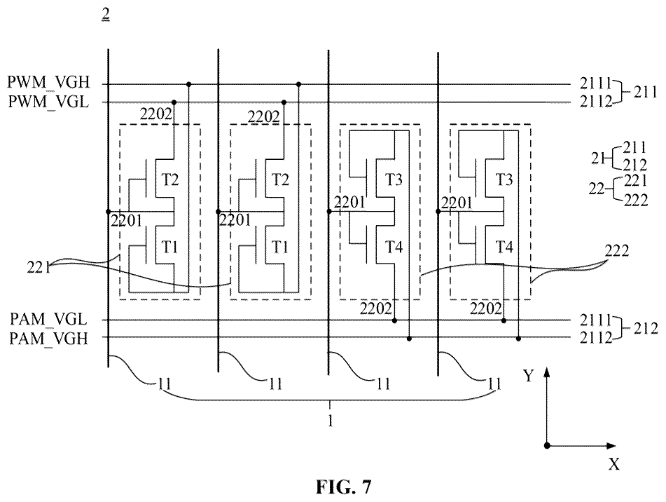

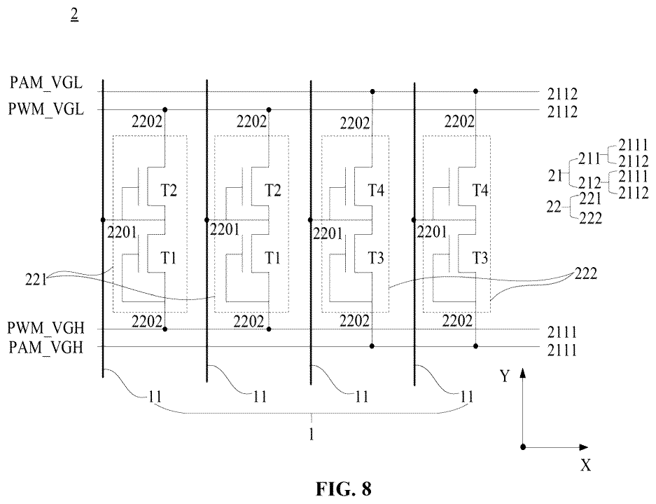

As another embodiment, optionally, FIG. 7 illustrates a structural schematic of a fourth display panel according to various embodiments of the present disclosure; and FIG. 8 illustrates a structural schematic of a fifth display panel according to various embodiments of the present disclosure. Referring to FIGS. 6-8, along the second direction Y, the first group of power signal lines 211 and the second group of power signal lines 212 may be respectively on two sides of the electrostatic discharge circuit 22 that are opposite to each other; or along the second direction Y, the first power signal lines 2111 in the first group of power signal lines 211 and the second group of power signal lines 212 may be on the first side of the electrostatic discharge circuit 22, and the second power signal line 2112 in the first group of power signal lines 211 and the second group of power signal lines 212 may be on the second side of the electrostatic discharge circuit 22.

For example, referring to FIGS. 6-7, along the second direction Y (i.e., the vertical direction), the first group of power signal lines 211 and the second group of power signal lines 212 may be respectively on two sides of the electrostatic discharge circuit 22 that are opposite to each other. That is, when the first power signal line 2111 and the second power signal line 2112 in the first group of power signal lines 211 are both on the side of the electrostatic discharge circuit 22 away from the first edge 3, correspondingly, the first power signal line 2111 and the second power signal line 2112 in the second group of power signal lines 212 may be both on the side of the electrostatic discharge circuit 22 adjacent to the first edge 3; or when the first power signal line 2111 and the second power signal line 2112 in the first group of power signal lines 211 are both on the side of the electrostatic discharge circuit 22 adjacent to the first edge 3, correspondingly, the first power signal line 2111 and the second power signal line 2112 in the second group of power signal lines 212 may be both on the side of the electrostatic discharge circuit 22 away from the first edge 3. In such way, normal discharge of the electrostatic voltage signal by the electrostatic discharge circuit 22 may be not affected, and the performance of the display panel may be ensured. It should be noted that FIG. 7 only exemplarily embodies that when the first power signal line 2111 and the second power signal line 2112 in the first group of power signal lines 211 are both on the side of the electrostatic discharge circuit 22 away from the first edge 3, the first power signal line 2111 and the second power signal line 2112 in the second group of power signal lines 212 may be both on the side of the electrostatic discharge circuit 22 adjacent to the first edge 3. For another situation mentioned above, appropriate adjustments may be made based on FIG. 7, which may not be described in detail herein.

Similarly, referring to FIGS. 6 and 8, along the second direction Y (i.e., the vertical direction), the first power signal lines 2111 in the first group of power signal lines 211 and the second group of power signal lines 212 may be on the first side of the electrostatic discharge circuit 22, and the second power signal lines 2112 in the first group of power signal lines 211 and the second group of power signal lines 212 may be on the second side of the electrostatic discharge circuit 22. The first side may be a side of the electrostatic discharge circuit 22 away from the first edge 3, and the second side may be a side of the electrostatic discharge circuit 22 adjacent to the first edge 3; or the first side may be a side of the electrostatic discharge circuit 22 adjacent to the first edge 3, and the second side may be a side of the electrostatic discharge circuit 22 away from the first edge 3. That is, when the first power signal lines 2111 in the first group of power signal lines 211 and the second group of power signal lines 212 are on the side of the electrostatic discharge circuit 22 away from the first edge 3, the second power signal lines 2112 in the first group of power signal lines 211 and the second group of power signal lines 212 may be on the side of the electrostatic discharge circuit 22 adjacent to the first edge 3. When the first power signal lines 2111 in the first group of power signal lines 211 and the second group of power signal lines 212 are on the side of the electrostatic discharge circuit 22 adjacent to the first edge 3, the second power signal lines 2112 in the first group of power signal lines 211 and the second group of power signal lines 212 may be on the side of the electrostatic discharge circuit 22 away from the first edge 3. In such way, normal discharge of the electrostatic voltage signal by the electrostatic discharge circuit 22 may be not affected, thereby ensuring the performance of the display panel. It should be noted that FIG. 8 only exemplarily embodies that when the first power signal lines 2111 in the first group of power signal lines 211 and the second group of power signal lines 212 are on the side of the electrostatic discharge circuit 22 away from the first edge 3, the second power signal lines 2112 in the first group of power signal lines 211 and the second group of power signal lines 212 may be on the side of the electrostatic discharge circuit 22 adjacent to the first edge 3. For another situation mentioned above, appropriate adjustments may be made based on FIG. 8, which may not be described in detail herein.

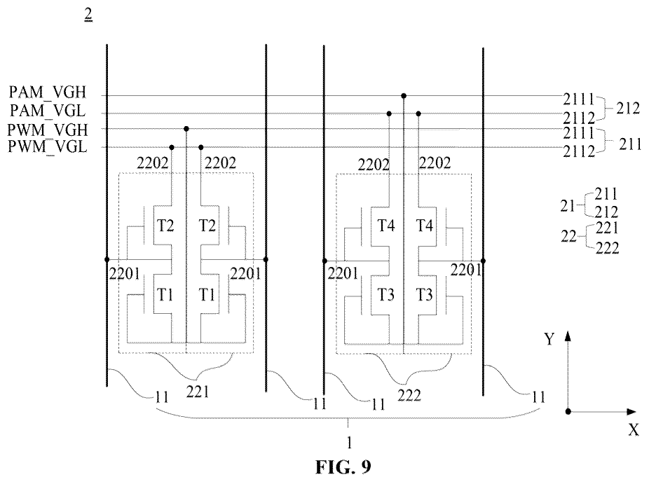

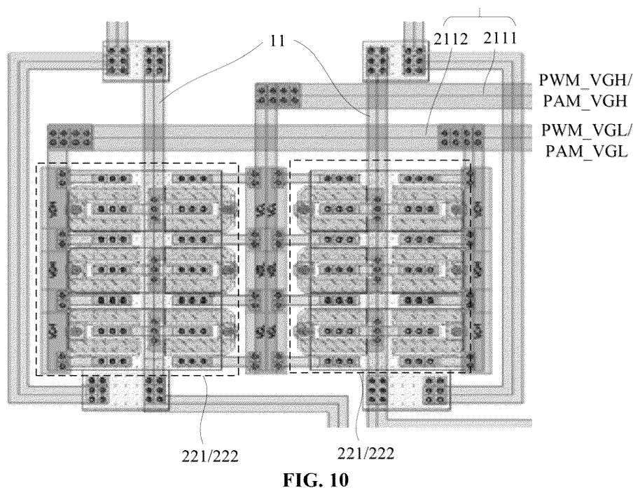

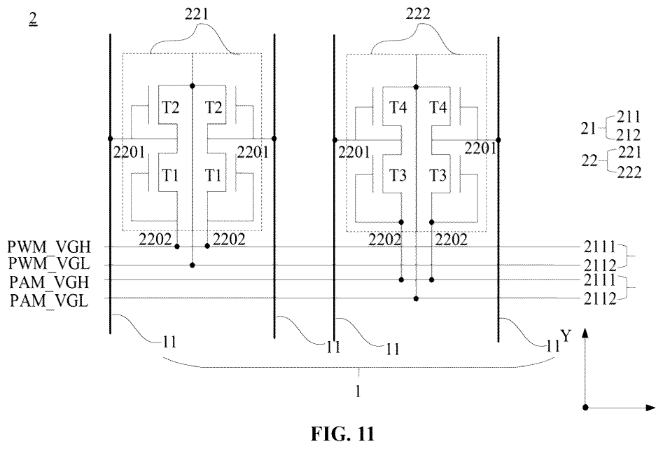

As another embodiment, optionally, FIG. 9 illustrates a structural schematic of a sixth display panel according to various embodiments of the present disclosure; FIG. 10 illustrates a structural schematic of circuit wiring of a sixth display panel according to various embodiments of the present disclosure; and FIG. 11 illustrates a structural schematic of a seventh display panel according to various embodiments of the present disclosure. Referring to FIGS. 6 and 9-11, along the first direction X, two first electrostatic discharge circuits 221 may be adjacent to each other, and the first signal lines 11 connected to two adjacent first electrostatic discharge circuits 221 may be respectively on two sides of two first electrostatic discharge circuits 221 that are opposite to each other; and along the first direction X, two second electrostatic discharge circuits 222 may be adjacent to each other, and the first signal lines 11 connected to two adjacent second electrostatic discharge circuits 222 may be respectively on two sides of two second electrostatic discharge circuits 222 that are opposite to each other.

For example, referring to the first electrostatic discharge circuit 221 on the left half shown in FIG. 9 and FIG. 11, the power signal line 21 in FIG. 9 may be on the side of the electrostatic discharge circuit 22 away from the first edge 3, and the power signal line 21 in FIG. 11 may be on the side of the electrostatic discharge circuit 22 adjacent to the first edge 3. Along the first direction X (i.e., the horizontal direction), when the electrostatic voltage signals on the first signal lines 11 are discharged from different power signal lines 21 by the electrostatic discharge circuits 22, the arrangement of the electrostatic discharge circuits 22 may also be that two first electrostatic discharge circuits 221 may be arranged to be adjacent to each other; and the first signal lines 11 connected to two adjacent first electrostatic discharge circuits 221 may be respectively on two sides of two first electrostatic discharge circuits 221 that are opposite to each other. That is, two adjacent first electrostatic discharge circuits 221 may be arranged back-to-back (on opposite sides) between corresponding two first signal lines 11. At this point, the first terminals 2201 of two first electrostatic discharge circuits 221 may be electrically connected back-to-back to corresponding first signal line 11, where two second terminals 2202 may be electrically connected to the first power signal lines 2111 in the first group of power signal lines 211, and may share one first power signal line 2111, such that the quantity of wires may be reduced, and the space utilization rate of the electrostatic discharge circuit 22 may be reduced.

Similarly, referring to the second electrostatic discharge circuit 222 on the right side shown in FIG. 9 and FIG. 11, the power signal line 21 in FIG. 9 may be on the side of the electrostatic discharge circuit 22 away from the first edge 3, and the power signal line 21 in FIG. 11 may be on the side of the electrostatic discharge circuit 22 adjacent to the first edge 3. Along the first direction X (i.e., the horizontal direction), when the electrostatic voltage signals on the first signal lines 11 are discharged from different power signal lines 21 by the electrostatic discharge circuits 22, the arrangement of the electrostatic discharge circuit 22 may also be that two second electrostatic discharge circuits 222 may be arranged adjacent to each other; and the first signal lines 11 connected to two adjacent second electrostatic discharge circuits 222 may be respectively on two sides of two second electrostatic discharge circuits 222 that are opposite to each other. That is, two adjacent second electrostatic discharge circuits 222 may be arranged back-to-back (on opposite sides) between corresponding two first signal lines 11. At this point, the first terminals 2201 of two second electrostatic discharge circuits 222 may be electrically connected back-to-back to corresponding first signal line 11, where two second terminals 2202 may be electrically connected to the first power signal lines 2111 in the second group of power signal lines 212, and may share one first power signal line 2111, such that the quantity of wires may be reduced, and the space utilization rate of the electrostatic discharge circuit 22 may be reduced.

In optional embodiments of the present disclosure, the display panel may further include the plurality of pixel circuits 12 and the plurality of light-emitting elements (not shown in drawings); same pixel circuit 12 may include the first module and the second module; and the plurality of first signal lines 11 may include a first sub-signal line 111 and a second sub-signal line 112, the first sub-signal line 111 may be electrically connected to the first electrostatic discharge circuit 221 and the first module, respectively, and the second sub-signal line 112 may be electrically connected to the second electrostatic discharge circuit 222 and the second module, respectively. The light-emitting element may be a micro-light-emitting diode, the first module and the second module may be circuit structures including transistors, the first module may be a pulse width modulation PWM (circuit), and the second module may be a pulse amplitude modulation PAM (circuit).

For example, referring to FIGS. 1, 4 and 6, the pixel driving region 1 may also include the plurality of pixel circuits 12 and the plurality of light-emitting elements; the pixel circuit 12 may include the pulse width modulation (PWM) circuit and the pulse amplitude modulation (PAM) circuit; the pixel circuit 12 may be configured to provide a driving current to the light-emitting element; the plurality of first signal lines 11 may include the first sub-signal line 111 and the second sub-signal line 112; the first sub-signal line 111 may be electrically connected to the first electrostatic discharge circuit 221 and the pulse width modulation (PWM) circuit respectively; and the second sub-signal line 112 may be electrically connected to the second electrostatic discharge circuit 222 and the pulse width modulation (PWM) circuit respectively.

The pixel circuit 12 may be a pixel circuit. In one embodiment, the pixel circuit 12 may include the pulse width modulation (PWM) circuit and the pulse amplitude modulation (PAM) circuit. The pixel circuit 12 may be configured to provide a driving current to the light-emitting element under the control of the pulse width modulation (PWM) circuit and the pulse amplitude modulation (PAM) circuit. The pulse width modulation (PWM) circuit may be configured to control the pulse width of the driving current, and the pulse amplitude modulation (PAM) circuit may be configured to control the pulse amplitude of the driving current. In such way, the light-emitting element may emit light of different brightnesses according to the amplitude of received driving current.

For example, the pixel circuit 12 may include the pulse width modulation (PWM) circuit and the pulse amplitude modulation (PAM) circuit, and the power signal voltages required by the pulse width modulation (PWM) circuit and the pulse amplitude modulation (PAM) circuit may be different. Therefore, when the electrostatic voltage signals generated by the pulse width modulation (PWM) circuit and the pulse amplitude modulation (PAM) circuit are electrostatically discharged, the plurality of first signal lines 11 may be divided into the first sub-signal line 111 and the second sub-signal line 112; and the first sub-signal line 111 may be electrically connected to the first electrostatic discharge circuit 221 and the pulse width modulation (PWM) circuit respectively, and the second sub-signal line 112 may be electrically connected to the second electrostatic discharge circuit 222 and the pulse width modulation (PWM) circuit respectively. In such way, when the electrostatic voltage signal generated by the pulse width modulation (PWM) circuit is electrostatically discharged, the electrostatic voltage signal may be transmitted to the first electrostatic discharge circuit 221 through the first sub-signal line 111, such that the first transistor T1 and the second transistor T2 in the first electrostatic discharge circuit 221 may be turned on to be in conduction. At this point, the electrostatic voltage signal may be transmitted to the first power signal line 2111 and the second power signal line 2112 of the first group of power signal lines 211 through the first electrostatic discharge circuit 221, and the electrostatic voltage signal may be discharged through the first power signal line 2111 and the second power signal line 2112 of the first group of power signal lines 211, thereby realizing rapid discharge of the electrostatic voltage signal generated by the pulse width modulation (PWM) circuit.

Similarly, when the electrostatic voltage signal generated by the pulse amplitude modulation (PAM) circuit is electrostatically discharged, the electrostatic voltage signal may be transmitted to the second electrostatic discharge circuit 222 through the second sub-signal line 112, such that the third transistor T3 and the fourth transistor T4 in the second electrostatic discharge circuit 222 may be turned on to be in conduction. At this point, the electrostatic voltage signal may be transmitted to the first power signal line 2111 and the second power signal line 2112 of the second group of power signal lines 212 through the second electrostatic discharge circuit 222, and the electrostatic voltage signal may be discharged through the first power signal line 2111 and the second power signal line 2112 of the second group of power signal lines 212, thereby realizing rapid discharge of the electrostatic voltage signal generated by the pulse amplitude modulation (PAM) circuit.

Optionally, referring to FIGS. 1 and 4, the first sub-signal line 111 may be electrically connected to the signal line that needs electrostatic discharge in the pulse width modulation (PWM) circuit; the second sub-signal line 112 may be electrically connected to the signal line that needs electrostatic discharge in the pulse amplitude modulation (PAM) circuit.

Optionally, referring to FIGS. 1 and 4, same first sub-signal line 111 may be electrically connected to one of the first scanning signal line S1, the second scanning signal line S2, the light control signal line EMIT and the sweep signal line SWEEP of the pulse width modulation (PWM) circuit; and same second sub-signal line 112 may be electrically connected to one of the first scanning signal line S1, the second scanning signal line S2, the light-emitting control signal line EMIT and the data signal line DATA of the pulse amplitude modulation (PAM) circuit.

For example, when the electrostatic voltage signal generated by the pulse width modulation (PWM) circuit is electrostatically discharged, the first sub-signal line 111 may need to be electrically connected to the signal line in the pulse width modulation (PWM) circuit that needs electrostatic discharge. Referring to FIG. 1, the signal lines that need electrostatic discharge in the pulse width modulation (PWM) circuit may include the first scanning signal line S1, the second scanning signal line S2, the light control signal line EMIT and the frequency sweeping signal line SWEEP; and the first scanning signal line S1, the second scanning signal line S2, the light control signal line EMIT and the frequency sweeping signal line SWEEP may be independent of each other. Therefore, the first scanning signal line S1, the second scanning signal line S2, the light control signal line EMIT and the frequency sweeping signal line SWEEP may need to be electrically connected to each other through the first sub-signal lines 111 independent of each other. For example, there are 4 signal lines that need electrostatic discharge in the pulse width modulation (PWM) circuit. Therefore, four first sub-signal lines 111 may be configured to be electrically connected to the first scanning signal line S1, the second scanning signal line S2, the light-emitting control signal line EMIT and the frequency sweeping signal line SWEEP respectively; and the electrostatic voltage signal generated by the pulse width modulation (PWM) circuit may be transmitted to the first group of power signal lines 211 for electrostatic discharge through the first electrostatic discharge circuit 221.

Similarly, when the electrostatic voltage signal generated by the pulse amplitude modulation (PAM) circuit is electrostatically discharged, the second sub-signal line 112 may need to be electrically connected to the signal line in the pulse amplitude modulation (PAM) circuit that needs electrostatic discharge. Referring to FIG. 1, the signal lines that need electrostatic discharge in the pulse amplitude modulation (PAM) circuit may include the first scanning signal line S1, the second scanning signal line S2, the light control signal line EMIT and the data signal line DATA; and the first scanning signal line S1, the second scanning signal line S2, the light control signal line EMIT and the data signal line DATA may be independent of each other. Therefore, the first scanning signal line S1, the second scanning signal line S2, the light control signal line EMIT and the data signal line DATA may be electrically connected to each other through the second sub-signal lines 112 independent of each other. For example, there are 4 signal lines in the pulse amplitude modulation (PAM) circuit that need electrostatic discharge. Therefore, four second sub-signal lines 112 may be configured to be electrically connected to the first scanning signal line S1, the second scanning signal line S2, the light control signal line EMIT and the data signal line DATA respectively; and the electrostatic voltage signal generated by the pulse amplitude modulation (PAM) circuit may be transmitted to the second group of power signal lines 212 for electrostatic discharge through the second electrostatic discharge circuit 222.

Optionally, the display panel of the present disclosure may include different circuits, where the lines in the first group of power signal lines 211 and the lines in the second group of power signal lines 212 may be from different circuits respectively. That is, the first power signal line 2111 and the second power signal line 2112 in the electrostatic discharge circuit 22 may reuse the signal lines in the driving circuit in the display panel, which may achieve the technical effect of above-mentioned embodiment and simplify the display panel.

For example, the driving circuit in the circuit may include the first driving circuit and the second driving circuit; and the first power terminal VGH and the second power terminal VGL in the first driving circuit and the second driving circuit may be respectively reused to different electrostatic discharge circuits 22.

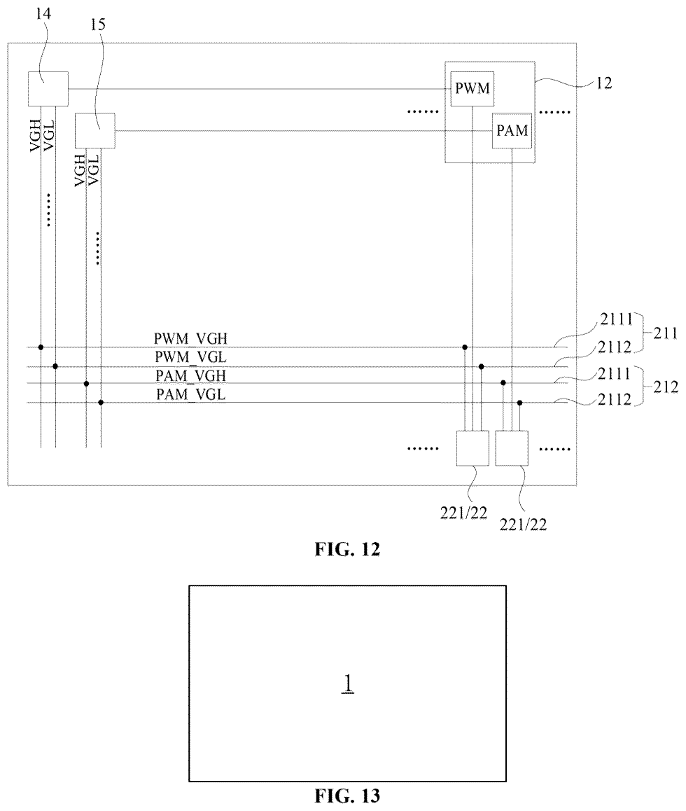

Optionally, FIG. 12 illustrates a structural schematic of connection relationship between shift register circuits, power signal lines, electrostatic discharge circuits and pixel circuits provided according to various embodiments of the present disclosure. Referring to FIGS. 2 and 12, the pixel driving region 1 may also include a plurality of cascaded first shift register circuits 14 and a plurality of cascaded second shift register circuits 15; the first shift register circuit 14 and the second shift register circuit 15 may both include the first power terminal VGH and the second power terminal VGL; in the first shift register circuit 14, the first power terminal VGH and the second power terminal VGL may be electrically connected to the first power signal line 2111 and the second power signal line 2112 in the first group of power signal lines 211 respectively; and in the second shift register circuit 15, the first power terminal VGH and the second power terminal VGL may be electrically connected to the first power signal line 2111 and the second power signal line 2112 in the second group of power signal lines 212, respectively.

The first shift register circuit 14 and the second shift register circuit 15 may be configured to provide scanning signals to correspondingly connected pixel circuits 12 to drive the pixel circuits 12 to operate. It may be understood that the shift register circuit in one embodiment may be the driving circuit shown in FIG. 2.

For example, the power voltages may be provided to the first shift register circuit 14 and the second shift register circuit 15 through the first power terminal VGH and the second power terminal VGL. The power voltage of the first power terminal VGH and the second power terminal VGL in the first shift register circuit 14 may be different from the power voltage of the first power terminal VGH and the second power terminal VGL in the second shift register circuit 15. After the power voltages are provided to the first shift register circuit 14 and the second shift register circuit 15, different pulse signals may be outputted under the control of the clock signal. For example, the pulse signal outputted in FIG. 2 may be a scanning pulse signal. In addition, in the first shift register circuit 14, by electrically connecting the first power terminal VGH and the second power terminal VGL to the first power signal line 2111 and the second power signal line 2112 in the first group of power signal lines 211 respectively, the electrostatic voltage signal of the first sub-signal line 111 may be inputted to the first power signal line 2111 and the second power signal line 2112 in the first group of power signal lines 211 after passing through the first electrostatic discharge circuit 221, that is, inputted to the first power terminal VGH and the second power terminal VGL; and finally electrostatic discharge may be performed on the electrostatic voltage signal through the first power terminal VGH and the second power terminal VGL. Similarly, in the second shift register circuit 15, by electrically connecting the first power terminal VGH and the second power terminal VGL to the first power signal line 2111 and the second power signal line 2112 in the second group of power signal lines 212 respectively, the electrostatic voltage signal of the second sub-signal line 112 may be inputted to the first power signal line 2111 and the second power signal line 2112 in the second group of power signal lines 212 after passing through the second electrostatic discharge circuit 222, that is, inputted to the first power terminal VGH and the second power terminal VGL; finally electrostatic discharge may be performed on the electrostatic voltage signal through the first power terminal VGH and the second power terminal VGL, which may ensure the electrostatic discharge circuit 22 to work normally and avoid leakage in non-electrostatic discharge stage.

It should be noted that FIG. 2 only shows an exemplary shift register circuit, and the pulse signal outputted by the shift register circuit may be a scanning pulse signal. In addition to the shift register circuit shown in FIG. 2, other shift register circuits may be configured to realize the output of other scanning signals, which may be configured according to actual conditions and may be not limited herein. In addition, FIG. 12 may only show corresponding connection relationship between the shift register circuits (the first shift register circuit 14 and the second shift register circuit 15), the pixel circuits 12 (including the pulse width modulation (PWM) circuit and the pulse amplitude modulation (PAM) circuit), the power signal lines 21 and the electrostatic discharge circuits 22 (the first electrostatic discharge circuit 221 and the second electrostatic discharge circuit 222). Specific positions and quantities of the shift register circuits, the pixel circuits 12 and electrostatic discharge circuits 22 may be only exemplary; and those skilled in the art may perform selection and design according to actual needs, which may not be limited herein.

Optionally, referring to FIGS. 1, 2 and 6, the pixel driving region 1 may also include the plurality of pixel circuits 12 and the plurality of light-emitting elements; the pixel circuit 12 may be configured to provide a driving current to the light-emitting element; the pixel circuit 12 may include the pulse width modulation (PWM) circuit and the pulse amplitude modulation (PAM) circuit; and the output terminal of the first shift register circuit 14 may be electrically connected to the pulse width modulation (PWM) circuit, and the output terminal of the second shift register circuit 15 may be electrically connected to the pulse amplitude modulation (PAM) circuit.

For example, when the pulse signal is inputted into the pulse width modulation (PWM) circuit, the output terminal of the first shift register circuit 14 may be electrically connected to the pulse width modulation (PWM) circuit, such that the pulse signal outputted by the first power terminal VGH and the second power terminal VGL through the first shift register circuit 14 may be inputted into the pulse width modulation (PWM) circuit. If the pulse width modulation (PWM) circuit needs multiple signal lines for electrostatic discharge, multiple first shift register circuits 14 may need to be configured, and the pulse signals outputted by all first shift register circuits 14 may be electrically connected to the signal lines of the pulse width modulation (PWM) circuit which needs electrostatic discharge, thereby realizing the pulse signals inputted to the pulse width modulation (PWM) circuit.

Similarly, when the pulse signal is inputted into the pulse amplitude modulation (PAM) circuit, the output terminal of the second shift register circuit 15 may be electrically connected to the pulse amplitude modulation (PAM) circuit, such that the pulse signal outputted by the first power terminal VGH and the second power terminal VGL through the second shift register circuit 15 may be inputted into the pulse amplitude modulation (PAM) circuit. If the pulse amplitude modulation (PAM) circuit needs multiple signal lines for electrostatic discharge, multiple second shift register circuits 15 may need to be configured, and the pulse signals outputted by all second shift register circuits 15 may be electrically connected to the signal lines of the pulse amplitude modulation (PAM) circuit which needs electrostatic discharge, thereby realizing the pulse signals inputted to the pulse amplitude modulation (PAM) circuit.

Through above-mentioned embodiment, the first shift register circuit 14 may receive the power signals of the first group of power signal lines 211 (that is, the high-level power signal PWM_VGH and the low-level power signal PWM_VGL) and provide the driving signal to the pulse width modulation (PWM) circuit, the output terminal of the first shift register circuit 14 may be electrically connected to the pulse width modulation (PWM) circuit; the first signal line 11 in the pulse width modulation (PWM) circuit may be electrically connected to the first electrostatic discharge circuit 221 to achieve electrostatic discharge; and the first electrostatic discharge circuit 221 may be also electrically connected to the first group of power signal lines 211 for electrostatic discharge. Therefore, the first shift register circuit 14, the pulse width modulation (PWM) circuit in the pixel circuit, the first electrostatic discharge circuit 221 and the first group of power signal lines 211 may be connected in sequence in a corresponding manner; and the first shift register circuit 14 and the first electrostatic discharge circuit 221 may reuse same group of power signal lines 21. Meanwhile, the voltage domains of the driving signal on the first signal line 11 and the power signal on the first group of power signal lines 211 connected at both terminals of the first electrostatic discharge circuit 221 may be adapted to each other. Therefore, in the absence of static electricity, the first electrostatic discharge circuit 221 may be normally in the off (turn-off) state, and the switch state of the first electrostatic discharge circuit 221 may not be affected by the problem of voltage domain mis-adaption (mismatch), which may ensure that the first electrostatic discharge circuit 221 may have no interference with the first signal line 11 in the non-electrostatic state, and the first electrostatic discharge circuit 221 may effectively discharge the static electricity on the first signal line 11 in the electrostatic state.

Similarly, the second shift register circuit 15 may receive the power signals of the second group of power signal lines 212 (that is, the high-level power signal PAM_VGH and the low-level power signal PAM_VG) and provide the driving signal to the pulse amplitude modulation (PAM) circuit; the output terminal of the second shift register circuit 15 may be electrically connected to the pulse amplitude modulation (PAM) circuit; the first signal line 11 in the pulse amplitude modulation (PAM) circuit may be electrically connected to the second electrostatic discharge circuit 222 to realize electrostatic discharge; and the second electrostatic discharge circuit 222 may be also electrically connected to the second group of power signal lines 211 for electrostatic discharge. Therefore, the second shift register circuit 15, the pulse amplitude modulation (PAM) circuit in the pixel circuit, the second electrostatic discharge circuit 222 and the second group of power signal lines 212 may be connected in sequence correspondingly; and the second shift register circuit 15 and the second electrostatic discharge circuit 222 may reuse same group of power signal lines. Meanwhile, the voltage domains of the driving signal on the first signal line 11 and the power signal on the first group of power signal lines 212 connected at both terminals of the second electrostatic discharge circuit 222 may be adapted to each other. Therefore, in the absence of static electricity, the second electrostatic discharge circuit 222 may be normally in the off (turn-off) state, and the switch state of the first electrostatic discharge circuit 221 may not be affected by the problem of voltage domain mis-adaptation (mismatch), which may ensure that the first electrostatic discharge circuit 221 may not interfere with the first signal line 11 in the non-electrostatic state, and the first electrostatic discharge circuit 221 may effectively discharge the static electricity on the first signal line 11 in the electrostatic state.

In other terms, the first module, the first driving circuit, and the first electrostatic discharge circuit 221 mentioned above-mentioned embodiment may be a set of combinations; the second module, the second driving circuit, and the second electrostatic discharge circuit 222 may be another set of combinations. For example, electrically connected VGH and VGL in the first driving circuit, on the one hand, may affect or determine the magnitudes of some signals in the first module, and on the other hand, may be used as the signal lines in the first module in the first electrostatic discharge circuit 221 for electrostatic protection through the first electrostatic discharge circuit 221. Therefore, the signal magnitude on the signal line in the first module may be matched with the electrostatic protection range of the electrostatic discharge circuit 22, which may achieve electrostatic protection more accurately without adding new signals (VGH/VGL).

Based on same inventive concept, embodiments of the present disclosure further provide a display apparatus. FIG. 13 illustrates a structural schematic of a display apparatus according to various embodiments of the present disclosure. Referring to FIG. 13, the display apparatus may include the display panel 1 provided by any embodiment of the present disclosure. Therefore, the display apparatus provided by embodiments of the present disclosure may have corresponding beneficial effects of the display panel provided by embodiments of the present disclosure, which may not be described in detail here. Exemplarily, the display apparatus may be an electronic device such as a mobile phone, a computer, a smart wearable device (e.g., a smart watch), and a vehicle-mounted display apparatus, which may not be limited in embodiments of the present disclosure.

It may be seen from above-mentioned embodiments that the present disclosure may at least achieve following beneficial effects.

For the technical solutions of the present disclosure, when the electrostatic voltage signals of the plurality of first signal lines are released, the first terminals of the first electrostatic discharge circuit and the second electrostatic discharge circuit may be electrically connected to different first signal lines, respectively; and the second terminals of the first electrostatic discharge circuit and the second electrostatic discharge circuit may be electrically connected to different power signal lines, respectively. In such way, the electrostatic voltage signal of the first signal line may be smoothly transmitted to the first terminals of the first electrostatic release circuit and the second electrostatic release circuit; and the first electrostatic discharge circuit and the second electrostatic discharge circuit may be turned on to be in conduction. After the electrostatic discharge circuits are turned on to be in conduction, the electrostatic voltage signals may be outputted to different power signal lines through the second terminals of the first electrostatic discharge circuit and the second electrostatic discharge circuit; and the electrostatic voltage signals may be electrostatically discharged through different power signal lines. By using above-mentioned apparatus, the second terminals of the first electrostatic discharge circuit and the second electrostatic discharge circuit may be electrically connected to different power signal lines respectively, which may realize accurate turn-on of the electrostatic discharge circuits, avoid leakage of the electrostatic discharge circuits, and ensure the quality and performance of the display panel.

The above may be only optional embodiments of the present disclosure and the technical principles used. Those skilled in the art understand that the present disclosure may be not limited to specific embodiments described in the present disclosure. It is obvious to those skilled in the art that various changes, readjustments, combinations and substitutions may be made without departing from the scope of protection of the present disclosure. Therefore, although the present disclosure is described in detail through above-mentioned embodiments, the present disclosure may be not limited to above-mentioned embodiments and may include more other equivalent embodiments without departing from the concept of the present disclosure. The scope of the present disclosure may be determined by the scope of attached claims.

What is claimed is:

1. A display panel, comprising:
a plurality of first signal lines;
a plurality of power signal lines; and
a plurality of electrostatic discharge circuits, wherein the plurality of electrostatic discharge circuits includes a first electrostatic discharge circuit and a second electrostatic discharge circuit; the first electrostatic discharge circuit includes a first terminal and a second terminal, and the second electrostatic discharge circuit includes a first terminal and a second terminal; the first terminals of the first electrostatic discharge circuit and the second electrostatic discharge circuit are electrically connected to different first signal lines respectively; and the second terminals of the first electrostatic discharge circuit and the second electrostatic discharge circuit are electrically connected to different power signal lines respectively.

2. The display panel according to claim 1, wherein:
the first terminals of the first electrostatic discharge circuit and the second electrostatic discharge circuit are electrostatic input terminals; the second terminals of the first electrostatic discharge circuit and the second electrostatic discharge circuit are electrostatic output terminals;
and a quantity of the electrostatic output terminals is at least two.

3. The display panel according to claim 1, wherein:
the plurality of power signal lines include a first group of power signal lines and a second group of power signal lines; and the first group of power signal lines includes a first power signal line and a second power signal line; and the second group of power signal lines includes a first power signal line and a second power signal line;
a power signal voltage of the first power signal line in the first group of power signal lines is V11, and a power signal voltage of the second power signal line in the first group of power signal lines is V12; and a power signal voltage of the first power signal line in the second group of power signal lines is V21, and a power signal voltage of the second power signal line in the second group of power signal lines is V22, wherein V11>V12, V21>V22, V11/V21, and V12/V22; and
two second terminals of the first electrostatic discharge circuit are electrically connected to the first power signal line and the second power signal line in the first group of power signal lines respectively; and two second terminals of the second electrostatic discharge circuit are electrically connected to the first power signal line and the second power signal line in the second group of power signal lines respectively.

4. The display panel according to claim 3, wherein:
$$( V 11 - V 21 ) \times ( V 12 - V 22 ) > 0$$

5. The display panel according to claim 3, wherein:
$$V 11 - V 21 = V 12 - V 22$$

6. The display panel according to claim 3, wherein:
$$V 11 - V 12 = V 21 - V 22$$

7. The display panel according to claim 3, wherein:
the first electrostatic discharge circuit includes a first transistor and a second transistor; a control terminal and a first terminal of the first transistor are both electrically connected to the first power signal line in the first group of power signal lines; a second terminal of the first transistor is electrically connected to a control terminal and a first terminal of the second transistor respectively, and is configured as the first terminal of the first electrostatic discharge circuit to be electrically connected to a first signal line; and a second terminal of the second transistor is electrically connected to the second power signal line in the first group of power signal lines;
the second electrostatic discharge circuit includes a third transistor and a fourth transistor;
a control terminal and a first terminal of the third transistor are both electrically connected to the first power signal line in the second group of power signal lines; a second terminal of the third transistor is electrically connected to a control terminal and a first terminal of the fourth transistor respectively, and is configured as the first terminal of the second electrostatic discharge circuit to be electrically connected to a first signal line; and a second terminal of the fourth transistor is electrically connected to the second power signal line in the second group of power signal lines.

8. The display panel according to claim 1, wherein:
the plurality of electrostatic discharge circuits is arranged along a first direction, and the first power signal line and the second power signal line extend along the first direction.

9. The display panel according to claim 8, wherein:
along a second direction, the first power signal line is on a side of an electrostatic discharge circuit adjacent to or away from a first edge of the display panel, and the second power signal line is on the side of the electrostatic discharge circuit adjacent to or away from the first edge of the display panel; and the first edge is an edge of the display panel closest to the electrostatic discharge circuit, wherein the second direction is perpendicular to the first direction.

10. The display panel according to claim 9, wherein:
along the second direction, the first power signal line and the second power signal line are both on the side of the electrostatic discharge circuit away from the first edge of the display panel.

11. The display panel according to claim 10, wherein:
along the second direction, the first group of power signal lines and the second group of power signal lines are respectively on two opposite sides of the electrostatic discharge circuit; or along the second direction, first power signal lines in the first group of power signal lines and the second group of power signal lines are on a first side of the electrostatic discharge circuit; and second power signal lines in the first group of power signal lines and the second group of power signal lines are on a second side of the electrostatic discharge circuit.

12. The display panel according to claim 8, wherein:
along the first direction, two first electrostatic discharge circuits are adjacent to each other; and first signal lines connected to the two first electrostatic discharge circuits adjacent to each other are respectively on two opposite sides of the two first electrostatic discharge circuits adjacent to each other; and
along the first direction, two second electrostatic discharge circuits are adjacent to each other; and first signal lines connected to the two second electrostatic discharge circuits adjacent to each other are respectively on two opposite sides of the two second electrostatic discharge circuits adjacent to each other.

13. The display panel according to claim 1, further including:
a plurality of pixel circuits and a plurality of light-emitting elements, wherein:
the plurality of pixel circuit includes a pulse width modulation circuit and a pulse amplitude modulation circuit;
the plurality of first signal lines include a first sub-signal line and a second sub-signal line; and
the first sub-signal line is electrically connected to the first electrostatic discharge circuit and the pulse width modulation circuit; and the second sub-signal line is electrically connected to the second electrostatic discharge circuit and the pulse width modulation circuit.

14. The display panel according to claim 13, wherein:
the first sub-signal line is electrically connected to a signal line in the pulse width modulation circuit that needs electrostatic discharge; and
the second sub-signal line is electrically connected to a signal line in the pulse amplitude modulation circuit that needs electrostatic discharge.

15. The display panel according to claim 14, wherein:
a same first sub-signal line is electrically connected to one of a first scanning signal line, a second scanning signal line, a light-emitting control signal line and a frequency-sweeping signal line of the pulse width modulation circuit; and
a same second sub-signal line is electrically connected to one of a first scanning signal line, a second scanning signal line, a light-emitting control signal line and a data signal line of the pulse amplitude modulation circuit.

16. The display panel according to claim 3, further including:
a plurality of cascaded first shift register circuits and a plurality of cascaded second shift register circuits, wherein a first shift register circuit includes a first power terminal and a second power terminal; a second shift register circuit includes a first power terminal and a second power terminal; in the first shift register circuit, the first power terminal and the second power terminal are electrically connected to the first power signal line and the second power signal line in the first group of power signal lines respectively; and in the second shift register circuit, the first power terminal and the second power terminal are electrically connected to the first power signal line and the second power signal line in the second group of power signal lines respectively.

17. The display panel according to claim 16, further including:
a plurality of pixel circuits and a plurality of light-emitting elements, wherein:
the plurality of pixel circuits includes a pulse width modulation circuit and a pulse amplitude modulation circuit; and an output terminal of the first shift register circuit is electrically connected to the pulse width modulation circuit, and an output terminal of the second shift register circuit is electrically connected to the pulse amplitude modulation circuit.

18. The display panel according to claim 1, further including:
a plurality of pixel circuits and a plurality of light-emitting elements, wherein the plurality of electrostatic discharge circuits is between the plurality of pixel circuits and a first edge of the display panel.

19. The display panel according to claim 18, wherein:
the first edge is disposed with side wires.

20. The display panel according to claim 1, wherein:
a signal range of a power signal line electrically connected to the first electrostatic discharge circuit is different from a signal range of a power signal line electrically connected to the second electrostatic discharge circuit.

21. The display panel according to claim 1, further including:
a plurality of pixel circuits and a plurality of light-emitting elements, wherein:
a same pixel circuit includes a first module and a second module; and
the plurality of first signal lines include a first sub-signal line and a second sub-signal line; the first sub-signal line is electrically connected to the first electrostatic discharge circuit and the first module respectively; and the second sub-signal line is electrically connected to the second electrostatic discharge circuit and the second module respectively.

22. The display panel according to claim 1, further including:
a plurality of light-emitting elements, wherein the plurality of light-emitting elements is micro-light-emitting diodes.

23. A display apparatus, comprising:
a plurality of first signal lines;
a plurality of power signal lines; and
a plurality of electrostatic discharge circuits, wherein the plurality of electrostatic discharge circuits includes a first electrostatic discharge circuit and a second electrostatic discharge circuit; the first electrostatic discharge circuit includes a first terminal and a second terminal, and the second electrostatic discharge circuit includes a first terminal and a second terminal; the first terminals of the first electrostatic discharge circuit and the second electrostatic discharge circuit are electrically connected to different first signal lines respectively; and the second terminals of the first electrostatic discharge circuit and the second electrostatic discharge circuit are electrically connected to different power signal lines respectively.
